(19) United States
(12) Patent Application Publication
(10) Pub. No.: US 2024/0222149 A1
(43) Pub. Date: Jul. 4, 2024

(54) INJECTOR FOR A SEMICONDUCTOR FABRICATION TOOL

(71) Applicant: Helios Technical Services, LLC, Cave Creek, AZ (US)

(72) Inventors: Mike HALPIN, Cave Creek, AZ (US); Steve BURCH, Scottsdale, AZ (US)

(21) Appl. No.: 18/398,893

(22) Filed: Dec. 28, 2023

Related U.S. Application Data
(60) Provisional application No. 63/436,024, filed on Dec. 29, 2022.

(51) Int. Cl. H01L 21/67; B05B 1/30

(52) U.S. Cl. CPC H01L 21/67017; B05B 1/3046

(57) ABSTRACT

The present invention generally relates to an injector for a semiconductor fabrication tool for dispensing a material into an interior volume of the fabrication tool during a fabrication process of a semiconductor wafer. The injector may have a micrometer that may be adjusted so as to totally stop the flow of material through the injector or the micrometer may be adjusted to allow a range of precisely controlled flow rates of material through the injection. The injector is also preferably able to be easily taken apart and cleaned in the field, thereby increasing the injectors useful lifetime.

### BACKGROUND OF THE INVENTION

### Field of the Invention

The present invention generally relates to one or more injectors for a semiconductor fabrication tool and, more specifically, to one or more injectors dispensing a material, such as a gas, into an interior volume of the semiconductor fabrication tool during a fabrication process of devices on a surface of one or more semiconductor substrates or wafers.

### Background

In semiconductor device manufacturing, wafer processing often involves the deposition of a high-quality thin film of material created on a surface of the wafer. These processes often involve the uniform deposition of material via exposure of the surface of the wafer to gases having carefully controlled compositions. These manufacturing processes or steps are often performed within a reaction chamber to provide the necessary controlled environment. The chamber may be sealed during wafer processing and allows precise control over the make-up of gases or gas vapors within the chamber.

One or more injectors may be used to control a flow rate of corresponding gases into the chamber. The one or more injectors may release the gases into an injector flange which directs the gases into the chamber. In some semiconductor processes, the gases start in a vapor phase as they enter the chamber and then condense to generate a solid phase of material. The solid phase of material may either descend from above and be deposited on the surface of the semiconductor wafer or the solid phase of material may be created as the gases interact with the surface of the wafer. The introduction of the gases into the chamber must be very precisely controlled to create a desired thickness and quality of material uniformly distributed over the surface of the semiconductor wafer.

### SUMMARY OF THE INVENTION

This Summary section is neither intended to be, nor should be, construed as being representative of the full extent and scope of the present disclosure. Additional benefits, features and embodiments of the present disclosure are set forth in the attached figures and in the description hereinbelow, and as described by the claims. Accordingly, it should be understood that this Summary section may not contain all of the aspects and embodiments claimed herein.

Additionally, the disclosure herein is not meant to be limiting or restrictive in any manner. Moreover, the present disclosure is intended to provide an understanding to those of ordinary skill in the art of one or more representative embodiments supporting the claims. Thus, it is important that the claims be regarded as having a scope including constructions of various features of the present disclosure insofar as they do not depart from the scope of the methods and apparatuses consistent with the present disclosure (including the originally filed claims). Moreover, the present disclosure is intended to encompass and include obvious improvements and modifications of the present disclosure.

The present invention generally relates to an injector for a semiconductor fabrication tool and, more specifically, an injector for dispensing a gas into an interior volume of the fabrication tool during a fabrication process of a semiconductor.

During various steps of a semiconductor device manufacturing process layers of material used to form structures are deposited over a surface of wafer substrates. The wafer substrate comprises semiconductor materials. These steps may involve the processing of the wafer substrate in a specific gaseous environment. To enable precise control over such fabrication steps, wafer processing often occurs within a sealed chamber that enables precise control over the internal environment of the chamber. One such factor that needs to be controlled is a flow rate of one or more materials into the chamber. As an example, it is often desirable during the fabrication process of a semiconductor to control the flow rate of one or more liquids and/or gases into the chamber.

An injector may be used to control the flow of material into the chamber. The injector may have a micrometer with a distal end that may be raised or lowered a very precise amount. The end of the micrometer may be positioned against a needle injector. A spring element may also be positioned against the needle injector to continually bias the needle against the micrometer. This allows the adjustment of the micrometer to very precisely move the needle injector in either an upward or downward direction.

The micrometer may raise or lower the needle injector inside of a housing seal jet. The needle injector may totally close a bottom hole of the housing seal jet to completely stop the flow of material through the injector or the needle injector may be raised some desired amount using the micrometer to allow a desired flow rate of material (e.g., a gas) out of the bottom hole of the housing seal jet.

The injector may also include a body injector with upper male threads that allow the micrometer and a cap to be removed from the top of the body injector and lower male threads that allow the injector to be attached to a device, such as an injector flange, for receiving the injector. The injector may also include a retaining ring that may be removed to allow access to all of the other parts of the injector.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 depicts an example of a semiconductor fabrication tool that may be used with the present invention.

FIG. 2 depicts an example of an injector flange and a plurality of injectors that may be used with the injector flange.

FIG. 3 depicts a three-dimensional illustration of a possible embodiment of an injector.

FIG. 4 depicts a cross-section view of the example injector in FIG. 3.

FIG. 5 depicts an exploded view of a three-dimensional illustration of a possible embodiment of an injector.

FIG. 6 depicts a cross-section view of the example injector in FIG. 5.

FIG. 7 depicts a three-dimensional illustration of an example micrometer.

FIG. 8 depicts a three-dimensional illustration of an example cap.

FIG. 9 depicts a three-dimensional illustration of an example band wear bearing.

FIG. 10 depicts a three-dimensional illustration of an example body injector.

FIG. 11 depicts a three-dimensional illustration of an example retaining ring.

FIG. 12 depicts a three-dimensional illustration of an example spring.

FIG. 13 depicts a three-dimensional illustration of an example needle injector.

FIG. 14 depicts a three-dimensional illustration of an example O-ring.

FIG. 15 depicts a three-dimensional illustration of an example pressure plate.

FIG. 16 depicts a three-dimensional illustration of an example seal.

FIG. 17 depicts a three-dimensional illustration of an example housing seal jet.

### DETAILED DESCRIPTION OF THE ILLUSTRATED EMBODIMENTS

The present invention generally relates to an injector for a semiconductor fabrication tool and, more specifically, an injector for dispensing a gas into an interior volume of the fabrication tool during a fabrication process of a semiconductor device.

During various steps of a semiconductor device manufacturing process device structures are formed over a surface of wafer substrates where the wafer substrate comprises semiconductor materials. These steps may involve the processing of the wafer substrate in a specific gaseous environment. To enable precise control over such fabrication steps, wafer processing often occurs within a sealed chamber that enables precise control over the internal environment of the chamber. One such factor that needs to be controlled is the rate of flow of material into the chamber. As an example, it is often desirable during the fabrication process of a semiconductor to control the flow rate of one or more gases into the chamber.

One problem with current injectors is that they are not easily or accurately calibrated. While it is very important to have precise control over the flow rates of the gases into the injector flange (and thus into the chamber), current injectors are difficult to calibrate, and the calibration is often not as accurate or as repeatable as desired. Without an easy and accurate method of calibrating the injectors, it is difficult to precisely control the flow rates of the gases into the chamber. The lack of a repeatable calibration process of the injectors hurts the yield rate of the semiconductor products thereby placing an undesirable financial burden on the semiconductor manufacturer as time and materials may be rendered worthless. Thus, an injector that is easily and accurately calibrated is needed.

Existing injectors are typically roughly calibrated by the injector manufacturer at the time the injector is created. However, once the injectors are put into use, they may get out of calibration due to the natural aging process of the injectors and by buildup of material on the injectors during use. Once out of calibration, current injectors either require a difficult and inaccurate calibration process or the injectors may have to be replaced. It would thus be desirable to be able to easily and accurately calibrate injectors onsite in the field, i.e., at the semiconductor manufacturer. Thus, an injector that is easily and accurately calibrated in the field is also needed.

Another problem with current injectors is that they do not have a zero stop that fully stops the flow of gases into the injector flange. There are times in operating the chamber during testing and other operations that it is desirable to know that the injector is in a totally closed position and that the gases have been completely shut off. Current injectors do not have a zero stop that may be easily used to insure they are closed. It would also be advantageous for the injector to have a zero stop that does not affect the calibration of the injector. This would reduce the number of times the injector needed to be calibrated and thus would save time in the manufacturing process of the semiconductors. Thus, an injector that has a zero stop that fully turns off the gases and does not change the calibration of the injector is also needed.

Another problem with current injectors is that they are not easily refurbished. The flow of gases through an injector's parts will deposit unwanted residue in the injector which can negatively impact the performance of the injector. This can lead to increased costs to the semiconductor manufacturer as current injectors cannot easily be repaired and therefore must be replaced as the injectors age. The reason current injectors are not easily refurbished is that they typically use a unibody design that prevents the injectors from being easily taken apart and cleaned. An injector that could be easily taken apart would allow its internal components to be easily and thoroughly cleaned, thereby extending the useful life of the injector and reducing replacement costs. Thus, an injector that is easy to take apart and clean to extend its useful life is also needed.

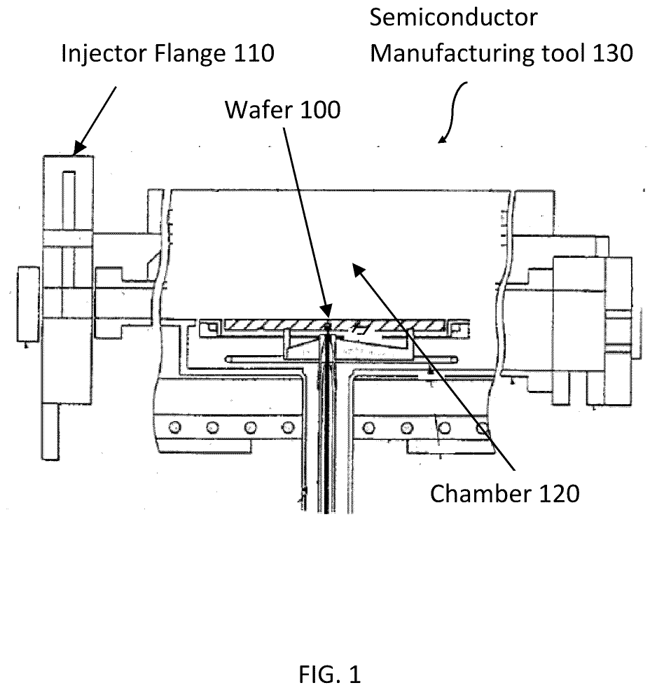

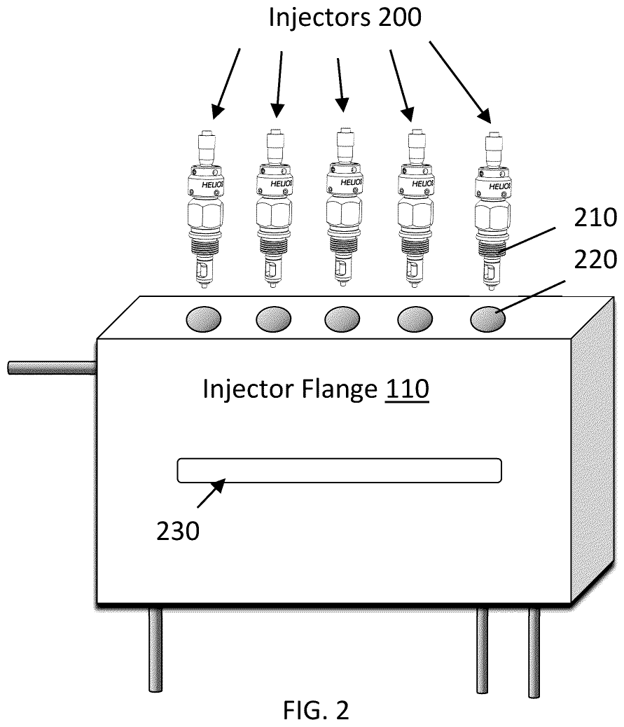

FIG. 1 depicts an example of a semiconductor manufacturing tool 130 that may be used with one or more injectors 200 (shown in FIGS. 2-6). It should be noted that the injectors 200 may be used in a wide variety of semiconductor manufacturing tools 130 to introduce a wide variety of materials into a chamber 120 of the semiconductor manufacturing tool 130. Thus, the injectors 200 of the present invention are not limited by the design of the semiconductor fabrication tool 103, the design of the chamber 120 or the materials that are being introduced into the chamber 120 unless expressly stated in the claims.

In the example chamber 120 illustrated in FIG. 1, one or more injectors 200 may be used to precisely control the release of one or more materials or gases into an injector flange 110. The gases in the injector flange 110 may travel from the injector flange 110 to the chamber 120 and be used to deposit material and/or form layers of a material on the wafer 100 during a semiconductor manufacturing process. In other embodiments, the injectors 200 may be attached directly to a chamber 120 of a semiconductor manufacturing tool 130 to control a flow of material or gases directly to the chamber 120.

FIG. 2 depicts an injector flange 110 with a plurality of threaded openings 220. In a preferred embodiment, one or more injectors 200 (five are illustrated in this specific example), each also having a lower male threads 210, may be screwed into the injector flange 110. The injectors 200 may be screwed into the injector flange 110 (or is some embodiments, the chamber 120) in an air-tight manner such that no material or gas can escape between the injectors 200 and the threaded openings 220. One or more gases may be routed to the injector flange 110 through air-tight conduits (not shown) with a corresponding one or more injectors 200 precisely controlling the flow of the gases from the conduits into the injector flange 110. The one or more gases may then be routed to the chamber 120 as shown in FIG. 1 through an aperture 230 in the injection flange 110. While an injector flange 110 was used as an example in FIG. 2, the one or more injectors 200 may also be used in other desired devices or chambers where the flow of a material, such as a liquid or a gas, is desired.

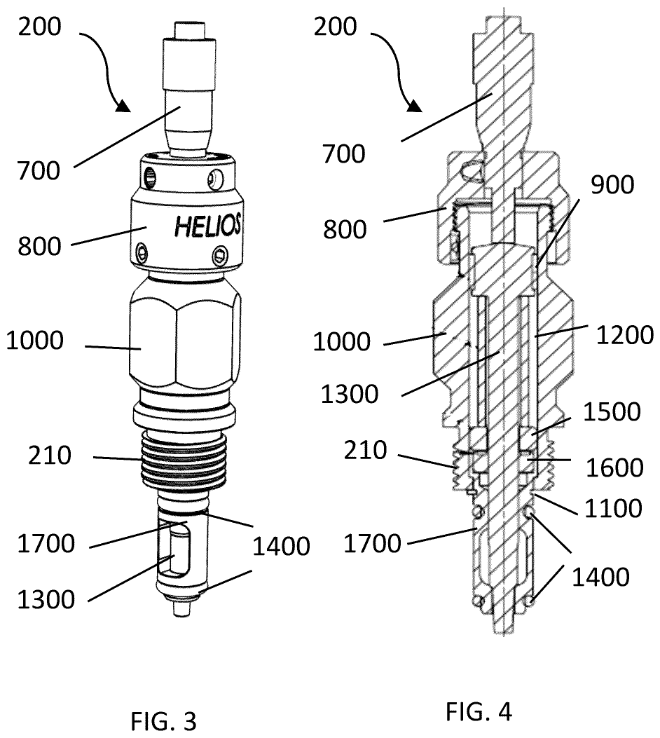

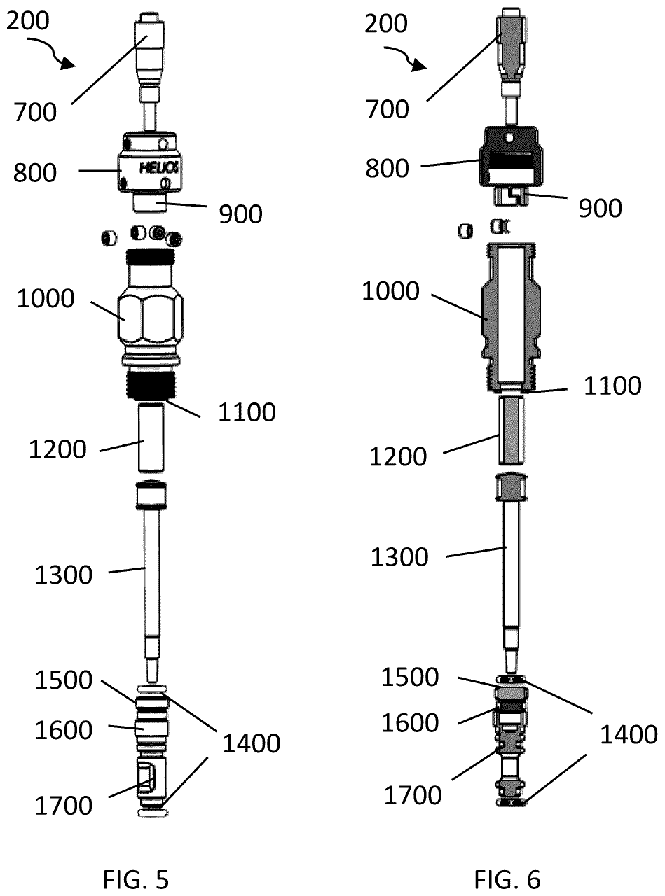

FIG. 3 depicts an example injector 200 and FIG. 4 depicts a cross section view of the example injector 200 in FIG. 3. FIG. 5 depicts an exploded view of the example injector 200 and FIG. 6 depicts a cross section view of the exploded view in FIG. 5. The example injector 200 in FIGS. 3-6 comprises a micrometer 700, a cap 800, a band wear bearing 900, a body injector 1000, a retaining ring 1100, a spring 1200, a needle injector 1300, two O-rings 1400, a pressure plate 1500, a seal 1600, and a housing seal jet 1700.

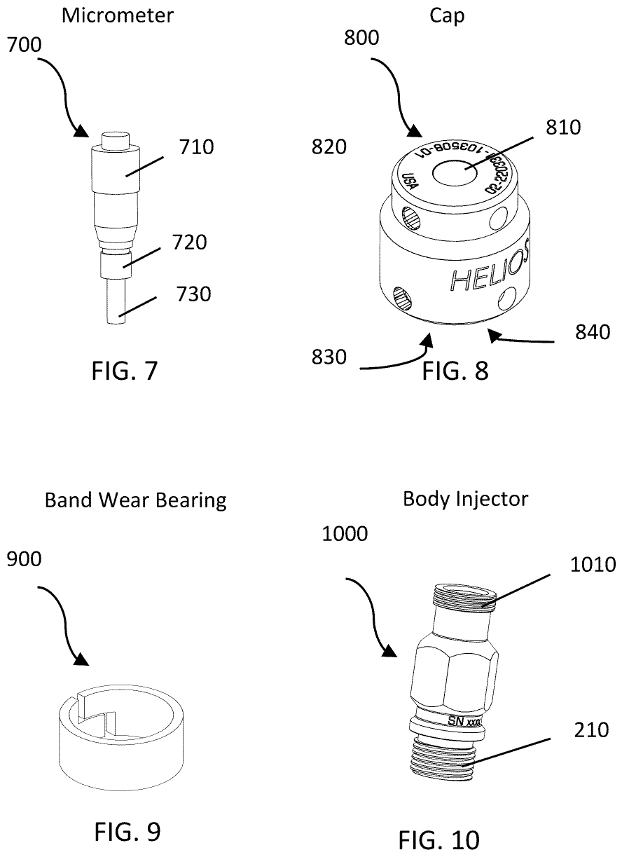

FIG. 7 illustrates an example of a micrometer 700 that may be used with the present invention. The micrometer 700 may have a grip surface 710 that is external to the injector 200 that may be twisted and rotated to adjust a flow of material through the injector 200 and a distal end 730 that extends into the interior of the injector 200. The micrometer 700 may be operably connected to the cap 800 using fine male threads 720 such that when the grip surface 710 of the micrometer 700 is turned, the distal end 730 of the micrometer 700 either extends into, or retracts from, the cap 800 and the injector 200. As one possible example, when the grip surface 710 of the micrometer 700 is turned clockwise, the distal end 730 of the micrometer 700 may extend further into the cap 800 and interior of the injector 200, while turning the grip surface 710 of the micrometer 700 counterclockwise may retract the distal end 730 of the micrometer 700 from the cap 800 and the interior of the injector 200. As another possible example, when the grip surface 710 of the micrometer 700 is turned counterclockwise, the distal end 730 of the micrometer 700 may extend further into the cap 800 and interior of the injector 200, while turning the grip surface 710 of the micrometer 700 clockwise may retract the distal end 730 of the micrometer 700 from the cap 800 and the interior of the injector 200.

FIG. 8 illustrates an example of a cap 800 that may be used with the present invention. The cap 800 preferably has a top opening 810 for receiving the micrometer 700. The top opening 810 may also have fine female threads 820 on the inside of the cap 800 that may engage with the fine male threads 720 of the micrometer 700. The cap 800 preferably has a portion, such as the fine female threads 820, for fixedly retaining and holding the fine male threads 720 of the micrometer 700. Engaging or meshing the fine male threads 720 of the micrometer 700 with the cap 800 allows for the turning of the grip surface 710 of the micrometer 700 to raise or lower the distal end 730 of the micrometer 700 in relation to the cap 800. The cap 800 may also have bottom fine female threads 820 located on the inside surface of a bottom opening 840 in the cap 800 that may be used to attach the cap 800 to upper male threads 1010 located on an outer surface of the body injector 1000.

FIG. 9 illustrates an example of a band wear bearing 900 that may be used with the present invention. As the grip surface 710 of the micrometer 700 is rotated, the distal end 730 of the micrometer 700 engages with the top end 1310 of the needle injector 1300. The needle injector 1300 is illustrated in FIG. 13. Depending on the direction the grip surface 710 of the micrometer 700 is rotated, the needle injector 1300 may be pushed down or raised up in the injector 200. The needle injector 1300 may have a surface 1320 that slides along the band wear bearing 900 when the micrometer 700 is adjusted.

FIG. 10 illustrates an example of a body injector 1000 that may be used with the present invention. The body injector 1000 may generally be shaped as a hollow cylinder and have upper male threads 1010 and lower male threads 210. The body injector 1000 may also be generally shaped as a nut to easily allow its installation and removal to, as a non-limiting example, an injector flange 110. In a preferred embodiment, the upper male threads 1010 may be used to connect the cap 800 to the body injector 1000 while the lower male threads 210 may be used to connect the body injector 1000 to the injector flange 110 or another chamber.

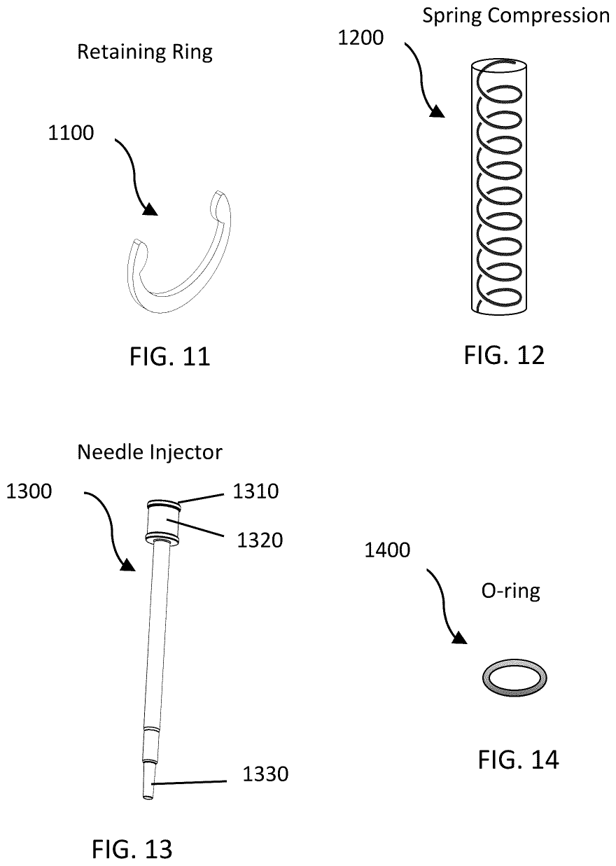

FIG. 11 illustrates an example of a retaining ring 1100 that may be used with the present invention. The retaining ring 1100 may be connected to the housing seal jet 1700, shown in FIG. 17, to retain the housing seal jet 1700 in operable position with the body injector 1000. As the retaining ring 1100 is easy to remove, the housing seal jet 1700 is detachably connected to the body injector 1000 in preferred embodiments.

FIG. 12 illustrates an example of a spring 1200 that may be used with the present invention. The spring 1200 is preferably in the shape of a hollow cylinder and is positioned inside the body injector 1000. The needle injector 1300 may fit inside the cylinder formed by the spring 1200. The spring 1200 may provide a biasing force that maintains an upward pressure against the needle injector 1300. Thus, in operation, the micrometer 700 may push the needle injector 1300 down against the biasing force of the spring 1200 or the spring 1200 may raise the needle injector 1300 when the micrometer 700 is adjusted upward. In this manner the needle injector 1300 may be raised or lowered through the use of the micrometer 700 and the spring 1200.

FIG. 13 illustrates an example of a needle injector 1300 that may be used with the present invention. The needle injector 1300 may be raised or lowered, i.e., moved, within an internal cavity formed by the inside of the body injector 1000 and the inside of the housing seal jet 1700 (illustrated in FIG. 17) of the injector 200 using the micrometer 700. Material, such as a liquid or a gas, may enter the orifice 1710 of the housing seal jet 1700. When the needle injector 1300 is fully lowered into the housing seal jet 1700 and a distal end 1330 of the needle injector 1300 comes into contact with an inner surface of the housing seal jet 1700, a zero stop position is created that prevents material flowing into the orifice 1710 of the housing seal jet 1700 from escaping out the bottom 1720 of the housing seal jet 1700, i.e., out of the injector 200. As the micrometer 700 is adjusted to start the flow of material through the injector 200, an opening between the needle injector distal end 1330 and an inner surface of the housing seal jet 1700 is created that allows material to flow through the injector 200. The size of this opening between the distal end 1330 of the needle injector 1300 and the inner surface of the housing seal jet 1700 may be very precisely controlled by adjusting the micrometer 700, which thereby precisely controls the flow rate of material through the injector 200.

FIG. 14 illustrates an example of an O-ring 1400 that may be used with the present invention. In a preferred embodiment two O-rings are used to prevent any leaks of material when connecting the housing seal jet 1700 portion of the injector 200 to a supply source of material, such as a liquid or a gas.

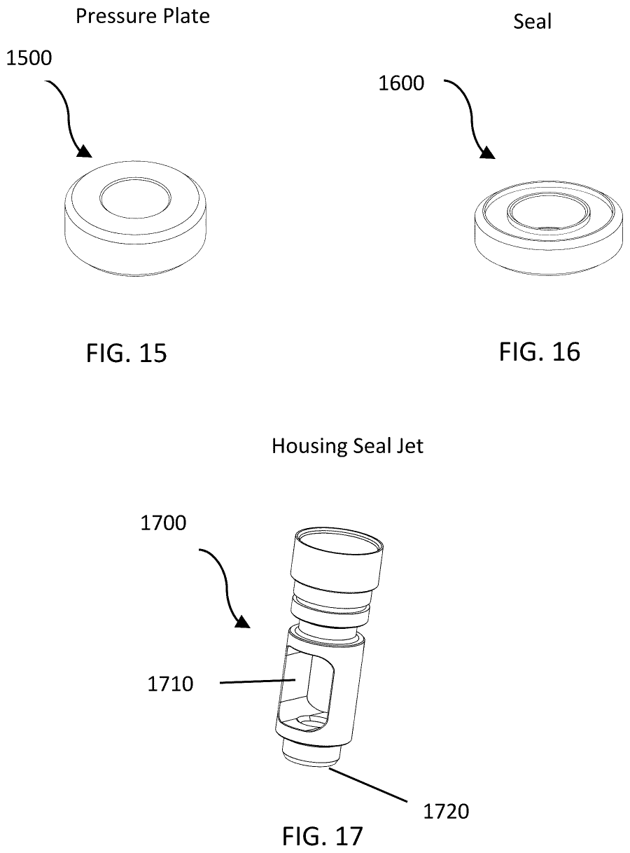

FIG. 15 illustrates an example of a pressure plate 1500 that may be used with the present invention. The pressure plate 1500 may be a rigid material formed in the shape of a doughnut and positioned inside the body injector 1000. As a non-limiting example, the pressure plate 1500 may be a wear band that is stiffer than a conventional O-ring and may provide a low-friction surface that enables the needle injector 1300 to easily slide up and down inside the injector body. The pressure plate 1500 may also be positioned inside the body injector 1000 so as to provide a fixed surface within the body injector 1000. The spring 1200 may be positioned against this fixed surface created by the pressure plate 1500 so that the spring 1200 may provide a continuous upward biasing force on the needle injector 1300.

FIG. 16 illustrates an example of a seal 1600 that may be used with the present invention. The seal 1600 may be made of a softer material formed in the shape of a doughnut and positioned inside the body injector 1000 against, and preferably below, the pressure plate 1500. The seal 1600 may prevent unwanted material from entering the body injector 1000 of the injector 200 during use.

The injector 200 as described is very easy to remove from the injector flange 110 and taken apart. The body injector 1000, while generally shaped as a hollow cylinder, may also have an outer surface generally shaped as a nut to allow a wrench to fit around the body injector 1000. This allows the injector 200 to be separated from the injector flange 110 with only a wrench. The wrench may be used to twist the body injector 1000, typically counterclockwise, around the body injector's lower male threads 210 to remove the injector from the injector flange 110.

Once the injector 200 is separated from the injector flange 110, the cap 800 may be removed by twisting the cap 800 and its female threads 820 around the upper male threads 1010 of the body injector 1000. This provides access to the internal parts of the injector 200 through the top of the body injector 1000. The retaining ring 1100 may also be removed from the housing seal jet 1700 which allows access to the internal parts of the injector 200 through the bottom of the body injector 1000. Thus, the injector 200 may be taken apart merely by twisting the cap 800 off and removing one retaining ring 1100. In this manner all of the components of the injector 200 may be cleaned, repaired, and/or replaced as needed. The injector 200 may be easily put back together by reversing the process of taking the injector 200 apart.

In should be noted that references to upward or downward in the specification are in relation to an injector 200 that is positioned vertically as shown in the figures. While the injector 200 may be used in any orientation, e.g., upside down, sidewise, etc. during actual operation, the upward or downward references should be understood as in relation to a vertically positioned injector 200 as shown in the figures.

It should also be noted that while the injector 200 was described as being used with an injector flange 110, the injector 200 is not so limited and may be used to control the flow rate of material into any desired chamber.

It should also be noted that threads that are described as male that mechanically engage, engage or mesh with threads that are described as female, for any of the parts previously discussed, could be reversed so that the male threads are now the female threads and the female threads are now the male threads. Male threads are defined to be grooves on the outside (externally) while female threads are defined to be grooves on the inside (internally).

It should also be noted that while the invention was described as using male and female threads to connect different pieces together, other methods, such as latches, bolts, retaining rings, etc. may also be used to connect the different pieces together.

The inventions and methods described herein can be viewed as a whole, or as a number of separate inventions, that can be used independently or mixed and matched as desired. All inventions, steps, processed, devices, and methods described herein can be mixed and matched as desired. All previously described features, functions, or inventions described herein or by reference may be mixed and matched as desired.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claims is:

1. An injector that precisely controls a flow rate of a material through the injector, comprising:
a micrometer having a grip surface and male threads, wherein the micrometer is configured so that the grip surface may be turned clockwise or counterclockwise by hand to adjust the flow rate of the material through the injector;
a cap having a top opening with top female threads to mechanically engage the male threads of the micrometer and a bottom opening with bottom female threads;
a body injector with upper male threads configured to mechanically engage the bottom female threads of the cap and lower male threads to mechanically engage female threads of an injector flange or a chamber;
a housing seal jet connected to the body injector, wherein the housing seal jet has an orifice for receiving a flow of a material;
a needle injector configured to move up and down inside an internal cavity formed at least by an inside of the body injector and an inside of the housing seal jet; and
a spring configured to be placed inside the internal cavity, wherein the micrometer is configured to push the needle injector down the internal cavity against a biasing force of the spring when the micrometer is adjusted downward and the biasing force of the spring is configured to raise the needle injector inside the internal cavity when the micrometer is adjusted upward.

2. The injector of claim 1, wherein the internal cavity is formed by the inside of the body injector, the inside of the housing seal jet and an inside of the cap.

3. The injector of claim 1, wherein the micrometer is configured to be able to move the needle injector inside the housing seal jet to a position that stops the flow of material through the injector.

4. The injector of claim 1, further comprising a retaining ring configured to detachably connect the housing seal jet to the body injector.

5. The injector of claim 1, further comprising a first o-ring and a second o-ring configured so that the first o-ring is attached to the housing seal jet above the orifice and the second o-ring is attached to the housing seal jet below the orifice.

6. The injector of claim 1, wherein the injector is configured to be connected to an injector flange for controlling the flow of a material into a chamber of a semiconductor tool.

7. The injector of claim 1, wherein the injector is configured to be connected to a chamber of a semiconductor tool.

8. An injector that precisely controls a flow rate of a material through the injector, comprising:
a micrometer having a grip surface and threads, wherein the micrometer is configured so that the grip surface may be turned clockwise or counterclockwise by hand to adjust the flow rate of the material through the injector;
a cap having a top opening with top threads to mechanically engage the threads of the micrometer and a bottom opening with bottom threads;
a body injector with upper threads configured to mechanically engage the bottom threads of the cap and lower threads to mechanically engage threads of a chamber;
a housing seal jet connected to the body injector, wherein the housing seal jet has an orifice for receiving a flow of a material;
a needle injector configured to move up and down inside an internal cavity formed at least by an inside of the body injector and an inside of the housing seal jet; and
a spring configured to be placed inside the internal cavity, wherein the micrometer is configured to push the needle injector down the internal cavity against a biasing force of the spring when the micrometer is adjusted downward and the biasing force of the spring is configured to raise the needle injector inside the internal cavity when the micrometer is adjusted upward.

9. The injector of claim 8, wherein the internal cavity is formed by the inside of the body injector, the inside of the housing seal jet and an inside of the cap.

10. The injector of claim 8, wherein the micrometer is configured to be able to move the needle injector inside the housing seal jet to a position that stops the flow of material through the injector.

11. The injector of claim 8, further comprising a retaining ring configured to detachably connect the housing seal jet to the body injector.

12. The injector of claim 8, further comprising a first o-ring and a second o-ring configured so that the first o-ring is attached to the housing seal jet above the orifice and the second o-ring is attached to the housing seal jet below the orifice.

13. The injector of claim 8, wherein the injector is configured to be connected to an injector flange for controlling the flow of a material into a chamber of a semiconductor tool.

14. The injector of claim 8, wherein the injector is configured to be connected to a chamber of a semiconductor tool.

15. An injector that precisely controls a flow rate of a material through the injector, comprising:
a micrometer having a grip surface, male threads and a distal end, wherein the micrometer is configured so that the grip surface may be turned clockwise or counterclockwise by hand to adjust the flow rate of the material through the injector;
a cap having a top opening with top female threads to mechanically engage the male threads of the micrometer and a bottom opening with bottom female threads;
a body injector with upper male threads configured to mechanically engage the bottom female threads of the cap and lower male threads to mechanically engage female threads of an injector flange or a chamber;
a housing seal jet connected to the body injector, wherein the housing seal jet has an orifice configured for controlling a flow of a material;
a needle injector configured to move up and down inside an internal cavity formed at least by an inside of the body injector and an inside of the housing seal jet; and
a spring configured to be placed inside the internal cavity, wherein the distal end of the micrometer is configured to push the needle injector down the internal cavity against a biasing force of the spring when the micrometer is adjusted downward and the biasing force of the spring is configured to raise the needle injector inside the internal cavity when the micrometer is adjusted upward.

16. The injector of claim 15, wherein the internal cavity is formed by the inside of the body injector, the inside of the housing seal jet and an inside of the cap.

17. The injector of claim 15, wherein the micrometer is configured to be able to move the needle injector inside the housing seal jet to a position that stops the flow of material through the injector.

18. The injector of claim 15, further comprising a retaining ring configured to detachably connect the housing seal jet to the body injector.

19. The injector of claim 15, further comprising a first o-ring and a second o-ring configured so that the first o-ring is attached to the housing seal jet above the orifice and the second o-ring is attached to the housing seal jet below the orifice.

20. The injector of claim 15, wherein the body injector has a section with a plurality of flat evenly spaced surfaces around the body injector configured to allow a wrench to be used to install the injector into the injector flange or the chamber.
